(19) United States
(12) Patent Application Publication
(10) Pub. No.: US 2026/0245495 A1
(43) Pub. Date: Aug. 20, 2026

(54) DISPLAY DRIVING DEVICE INCLUDING PIXEL INSPECTION FUNCTION AND DISPLAY DEVICE

(71) Applicant: SAPIEN SEMICONDUCTORS INC., Gyeonggi-do (KR)

(72) Inventors: Je Woo SEONG, Gyeonggi-do (KR); Jin Woong JANG, Gyeonggi-do (KR); Jihaeng LEE, Gyeonggi-do (KR)

(73) Assignee: SAPIEN SEMICONDUCTORS INC., Gyeonggi-do (KR)

(21) Appl. No.: 18/834,222

(22) PCT Filed: Feb. 2, 2024
(86) PCT No.: PCT/KR2024/001594

§ 371 Date: Jul. 29, 2024

(30) Foreign Application Priority Data
Apr. 27, 2023 (KR) 10-2023-0055506

(51) Int. Cl. G09G 3/32; G09G 3/20

(52) U.S. Cl. CPC G09G 3/32; G09G 3/2037; G09G 3/2074; G09G 2300/0842; G09G 2300/0871; G09G 2320/029; G09G 2320/0673; G09G 2320/0693; G09G 2330/12

(57) ABSTRACT

Provided are a display driving device having a pixel function and a display device. The display driving device includes a driving circuit unit in which a plurality of pixel driving circuits are arranged in rows and columns, a first controller connected to the plurality of pixel driving circuits on a row-by-row basis, a second controller connected to the plurality of pixel driving circuits on a column-by-column basis, and one or more inspection circuits electrically connected to an inspection target pixel driving circuit selected by the first controller and the second controller to extract an inspection signal of the inspection target pixel driving circuit.

### TECHNICAL FIELD

The present invention relates to a display driving device having a pixel inspection function, and a display device.

### BACKGROUND ART

As a next-generation display technology, micro light-emitting diodes (LEDs) are in the spotlight for the demand for small pixel size displays or high-quality image output. Micro LEDs have advantages over existing display technologies, such as small size, high contrast ratio, fast response speed, brightness, etc.

Meanwhile, recent industries require high integration and low power consumption, and to this end, pixels or display devices are produced by bonding a backplane including a driving circuit to a light-emitting element substrate including a light-emitting element.

However, there is a problem in checking whether normal operation is performed when the backplane and the light-emitting device substrate are bonded, and even if a problem is found, it is difficult to determine whether the discovered problem is related to the backplane or the light-emitting device substrate.

The above-mentioned background technology is technical information that the inventor possessed for deriving the present disclosure or acquired in the process of deriving the present disclosure, and may not be necessarily said to be known art disclosed to the general public before filing the application of the present disclosure.

### DISCLOSURE

### Technical Problem

The present disclosure relates to a display driving device having a pixel inspection function, and a display device. The problem that the present disclosure aims to solve is not limited to the problems mentioned above, and other problems and advantages of the present disclosure that are not mentioned can be understood through the following description and can be understood more clearly by the examples of the present disclosure. In addition, it will be appreciated that the problems and advantages to be solved by the present disclosure may be realized by means and combinations thereof indicated in the claims.

### Technical Solution

A first aspect of the present disclosure provides a display driving device including a driving circuit unit in which a plurality of pixel driving circuits are arranged in rows and columns, a first controller connected to the plurality of pixel driving circuits on a row-by-row basis, and a second controller connected to the plurality of pixel driving circuits on a column-by-column basis, in which the driving circuit unit includes an active area related to light emission and non-light emission of a light-emitting element in a driving mode and an inactive area not related to light emission and non-light emission of the light-emitting element in the driving mode, and the first controller and the second controller set a pixel driving circuit to be inspected in an inspection mode.

A second aspect of the present disclosure provides a light-emitting element array including a plurality of light-emitting elements and a display driving device, in which the display driving device may provide a display device that is the display driving device according to the first aspect.

A third aspect of the present disclosure provides a display driving device including a driving circuit unit in which a plurality of pixel driving circuits are arranged in rows and columns, a first controller connected to the plurality of pixel driving circuits on a row-by-row basis, a second controller connected to the plurality of pixel driving circuits on a column-by-column basis, and one or more inspection circuits electrically connected to an inspection target pixel driving circuit selected by the first controller and the second controller to extract an inspection signal of the inspection target pixel driving circuit.

### Advantageous Effects

According to various embodiments of the present disclosure, performance of a display driving device may be inspected both in a state in which a light-emitting element is coupled thereto and in a state in which the light-emitting element is not coupled thereto.

In addition, according to various embodiments of the present disclosure, not only the entire display driving device but also each driving circuit may be inspected, and even current characteristics as well as normal operation may be identified.

Furthermore, various embodiments of the present disclosure may be effective and economical because an inspection function is implemented using the driving circuit included in an inactive area.

Moreover, according to various embodiments of the present disclosure, a high-quality display device that displays appropriate gray levels may be manufactured by measuring a voltage applied to the light-emitting element and adjusting driving current based on the same.

### BRIEF DESCRIPTION OF DRAWINGS

FIG. 1 is a diagram schematically showing a manufacturing process of a display device according to an embodiment of the present disclosure.

FIG. 2 is a diagram schematically showing a display device according to an embodiment of the present disclosure.

FIGS. 3A and 3B are schematic diagrams for describing implementation of an inspection function according to two embodiments of the present disclosure;

FIG. 4 is a schematic diagram for describing an active area and an inactive area of a driving circuit unit related to a first inspection method, according to the present disclosure.

FIGS. 5A and 5B are diagrams schematically showing a display driving device according to an embodiment related to the first inspection method of the present disclosure.

FIG. 6 shows a current amplifying circuit for amplifying test current according to an embodiment of the present disclosure.

FIG. 7 is a diagram schematically showing a display driving device coupled to a light-emitting element array according to an embodiment related to a second inspection method of the present disclosure.

FIG. 8 is a diagram for specifically describing an inspection method according to an embodiment related to the second inspection method of the present disclosure.

FIG. 9 is a circuit diagram for describing an inspection circuit according to an embodiment related to the second inspection method of the present disclosure.

FIG. 10 is a graph for describing voltage characteristics analyzed using an inspection method according to an embodiment related to the second inspection method of the present disclosure.

FIG. 11 is a diagram schematically showing a display device according to an embodiment of the present disclosure.

FIG. 12 is a circuit diagram showing a pixel PX according to an embodiment of the present disclosure.

### BEST MODE

A display driving device according to an embodiment of the present disclosure includes a driving circuit unit in which a plurality of pixel driving circuits are arranged in rows and columns, a first controller connected to the plurality of pixel driving circuits in row units, and a plurality of pixel driving circuits in column units. It may include a second controller connected to one or more inspection circuits electrically connected to the inspection target pixel driving circuit selected by the first controller and the second controller to extract an inspection signal of the inspection target pixel driving circuit.

### Mode for Invention

Advantages and features of the present disclosure, and a method of achieving them will be apparent with reference to the embodiments described in detail in conjunction with the drawings. However, the present disclosure is not limited to the embodiments presented below, but may be implemented in various different forms, and should be understood to include all transformations, equivalents, and substitutes included in the spirit and technical scope of the present disclosure. Embodiments presented below are provided to complete the disclosure of the present disclosure and perfectly inform those of ordinary skill in the art of the category of the present disclosure. In describing the present disclosure, if it is determined that a detailed description of related known technologies may obscure the gist of the present disclosure, the detailed description thereof will be omitted.

The terms used in the embodiments are general terms that are currently widely used as much as possible, but may vary depending on the intention or precedent of a person working in the art, the emergence of new technology, etc. In addition, in a specific case, the applicant voluntarily may select terms, and in this case, the meaning of the terms may be disclosed in a corresponding description part of the disclosure. Thus, the terms used in herein should be defined not by the simple names of the terms but by the meaning of the terms and the contents throughout the specification.

The term used herein is used to describe particular embodiments, and is not intended to limit the present disclosure. Singular forms may include plural forms unless apparently indicated otherwise contextually. Herein, it should be understood that the term “include”, “have”, or the like used herein is to indicate the presence of features, numbers, steps, operations, components, parts, or a combination thereof described in the specifications, and does not preclude the presence or addition of one or more other features, numbers, steps, operations, components, parts, or a combination thereof.

In addition, terminology, such as “first” or “second” used herein, can be used to describe various components, but the components should not be limited by the terms. These terms are used to distinguish one component from another component.

In the following embodiment, “ON” used in connection with a device state may refer to an activated state of the device, and “OFF” may refer to a deactivated state of the device. “ON”, as used in connection with a signal received by a device, may refer to a signal that activates the device, and “OFF” may refer to a signal that deactivates the device. The device may be activated by high or low voltage. For example, a P-type transistor may be activated by low voltage. An N-type transistor may be activated by high voltage. Accordingly, it should be understood that “ON” voltages for a P-type transistor and an N-type transistor have opposite (low vs. high) voltage levels.

When one element is referred to as being “connected to” another element, it includes both direct connection to the other element or intervening another element therebetween.

Hereinafter, specific embodiments of the present disclosure will be described in detail with reference to the drawings.

In addition, in describing the disclosure in detail, if it is determined that a detailed description of a related known function or configuration may unnecessarily obscure the subject matter of the disclosure, the detailed description will be omitted.

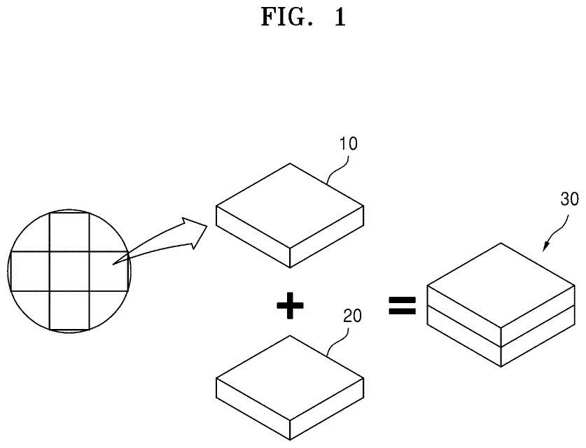

FIG. 1 is a diagram schematically showing a manufacturing process of a display device according to an embodiment of the present disclosure.

Referring to FIG. 1, a display device 30 according to an embodiment may include a light-emitting element array 10 and a display driving device 20. The light-emitting element array 10 may be coupled to the display driving device 20. The display driving device 20 may also be referred to as a driving circuit board.

The light-emitting element array 10 may include a plurality of light-emitting elements. The light-emitting element may be a light-emitting diode (LED). At least one light-emitting element array may be manufactured by growing a plurality of LEDs on a semiconductor wafer (SW). Accordingly, the display device 30 may be manufactured by coupling the light-emitting element array 10 to the display driving device 20 without a need to individually transfer an LED to the display driving device 20.

A driving circuit (a pixel driving circuit) corresponding to each light-emitting element on the light-emitting element array 10 may be arranged on the display driving device 20. The light-emitting element on the light-emitting element array 10 and the driving circuit on the display driving device 20 may be electrically connected to form a pixel PX. The display driving device 20 may also include a driving circuit array manufactured by growing a plurality of driving circuits on an SW.

One way to inspect whether driving circuits are produced normally and operate normally after manufacturing the display driving device 20 (or a driving circuit array) may be connecting the output of the open light-emitting element connection portion of the driving circuit to the outside. However, the display driving device 20 may include millions of driving circuits, and it may be impossible or inefficient to externally connect the outputs of the connections corresponding to the millions.

As a solution to this, the present disclosure may propose a display driving device and the display device 30 in which an operation for each driving circuit included in the display driving device 20 or each pixel PX included in the display device 30 may be individually inspected and an individual electrical feature may be identified.

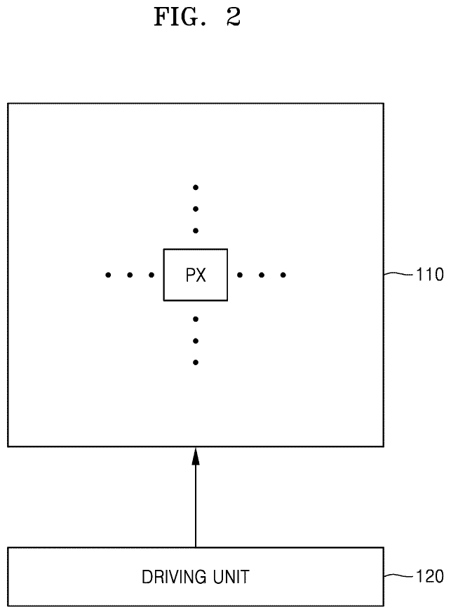

FIG. 2 is a diagram schematically showing a display device according to an embodiment of the present disclosure.

Referring to FIG. 2, the display device may include a pixel unit 110 and a driving unit 120. The display device of FIG. 2 may correspond to the display device 30 described above with reference to FIG. 1.

The pixel unit 110 may display an image using an n-bit digital image signal capable of representing 1 to 2ⁿ gray scales. The pixel unit 110 may include a plurality of pixels (PX) arranged in various patterns such as a predetermined pattern, for example, a matrix type or a zigzag pattern. A pixel PX emits one color, for example, one of red, blue, green, and white. Pixels PX may emit colors other than red, blue, green, and white.

The pixel PX may include a light-emitting element. The light-emitting element may be a self-luminous device. For example, the light-emitting device may be a light-emitting diode (LED). The light-emitting element may be a micro-to nano-scale LED. The light-emitting element may emit light at a single peak wavelength or may emit light at a plurality of peak wavelengths.

The pixel PX may further include a driving circuit connected to the light-emitting element. The driving circuit may be implemented by a semiconductor stacked structure on a substrate.

The driving unit 120 may drive and control the pixel unit 110. The driving unit 120 may include a controller (not shown), a gamma setting unit (not shown), a data driving unit (not shown), a current supplying unit (not shown), and a clock generating unit (not shown), but details will be described later.

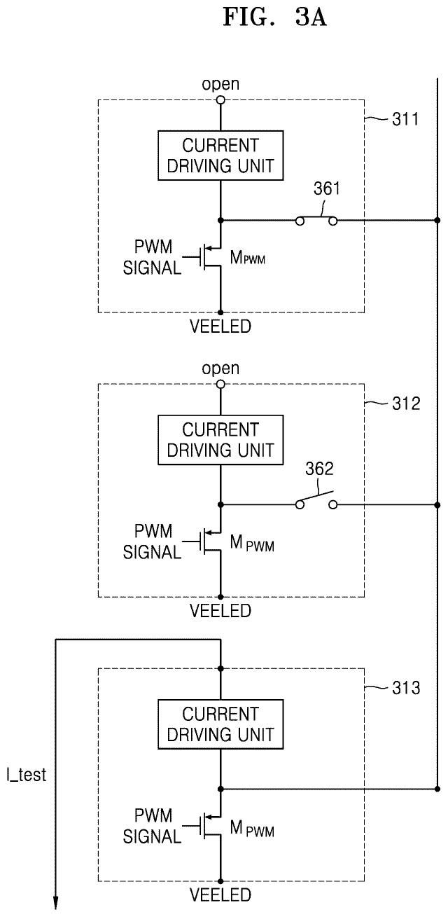

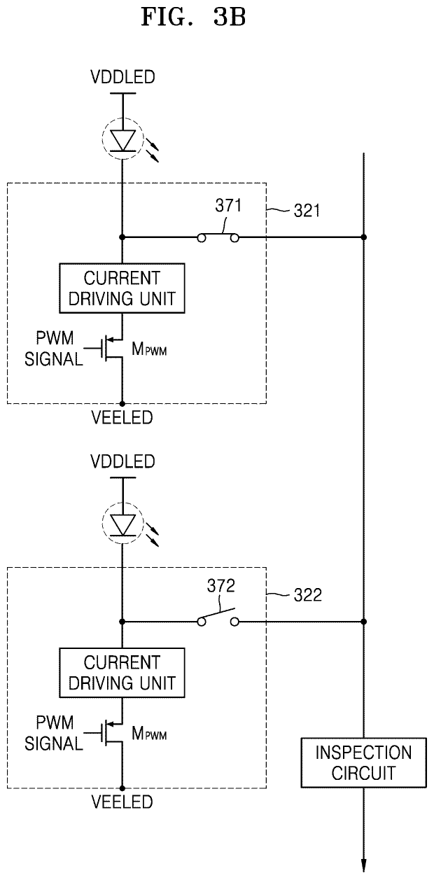

FIGS. 3A and 3B are schematic diagrams for describing the implementation of an inspection function according to two embodiments of the present disclosure.

The driving circuits of FIGS. 3A and 3B show some of components for convenience of understanding. Each of the driving circuits in FIGS. 3A and 3B may include a current driver and a PWM switch M_{PWM}.

The current driving unit of the driving circuit may supply driving current to cause the light-emitting element to emit light. The PWM switch M_{PWM} may control the on/off of the light-emitting element according to a PWM signal. The PWM signal may correspond to grayscale data stored in the pixel internal memory (not shown).

In one embodiment, the current driving unit may be an analog element that processes signals based on analog signals, and may include a transistor. In one embodiment, the PWM switch M_{PWM} may be a digital element that processes signals based on digital signals, and may include a transistor.

In the present disclosure, two inspection methods are described, and the display driving device or display device according to the present disclosure may implement an inspection function through at least one of the two inspection methods. Hereinafter, for convenience of description, the two inspection methods will be referred to as a first inspection method and a second inspection method, respectively.

In the present disclosure, the first inspection method is a method of inspecting only a driving circuit included in a display driving device, in which an inspection signal of a driving circuit to be inspected is output through a light-emitting element connection portion of the driving circuit in an inactive area in a state where the light-emitting element connection portion of the driving circuit to be inspected is open. On the other hand, in the present disclosure, the second inspection method is a method of inspecting operations of a current driving unit and a PWM switch when a light-emitting element is not connected, or inspecting characteristics of a light-emitting element when the light-emitting element is connected, in which the inspection signal of the driving circuit to be inspected is output through an inspection circuit.

There are differences between the first inspection method and the second inspection method according to the present disclosure, such as an inspection environment, a connection scheme of a built-in switch, presence or absence of an inspection circuit, use of an inactive area, an inspection signal extraction scheme, etc.

FIG. 3A schematically shows a connection state of circuits in an inspection mode according to the first inspection method.

In FIG. 3A, a driving circuit 311 may be a driving circuit selected as an inspection target, a driving circuit 312 may be a driving circuit not selected as an inspection target, and a driving circuit 313 may be a driving circuit included in an inactive area (or an inspection function implementation area). The inactive area and the inspection function implementation area will be described in detail later. In an embodiment, the driving circuit 311, the driving circuit 312, and the driving circuit 313 may be driving circuits included in one column.

As described above, the first inspection method may be a method for inspecting the driving circuits included in the display driving device before the light-emitting element array is coupled, and accordingly, the light-emitting element connection portion of the driving circuits shown in FIG. 3A may be open. Specifically, the light-emitting element connection portions of the driving circuit 311 and the driving circuit 312 may be open.

In the first inspection method, the driving circuit 313 may include a path formed on the light-emitting element connection portion to extract an inspection signal. That is, in the first inspection method, the driving circuit 313 included in the inactive area may serve to provide an electrical connection such that an inspection signal for inspection of the operation of the driving circuit selected as the inspection target may be extracted. Therefore, even if a light-emitting element array is coupled to the display driving device according to the first inspection method, the light-emitting element may not be connected to the driving circuit 313. In an embodiment, the inspection signal may be test current.

Referring to FIG. 3A, the driving circuit 311 is electrically connected to the driving circuit 313, but the driving circuit 312 may not be electrically connected to the driving circuit 311 and the driving circuit 313. Specifically, the driving circuit 311 may be electrically connected to a test line, the test line may be electrically connected to the driving circuit 313, and the inspection signal extracted through the test line may be received by, for example, a second controller 1020 to be described later.

In the present disclosure, driving circuits (e.g., the driving circuit 311 and the driving circuit 312) included in the active area may include a built-in switch having an adjustable electrical connection with the corresponding test line. When selected as an inspection target, a built-in switch included in the driving circuit is closed, thereby forming an electrical connection between the driving circuit and the test line. Referring to FIG. 3A, a built-in switch 361 of the driving circuit 311 selected as an inspection target may be in a closed state, but a built-in switch 362 of the driving circuit 312 not selected as an inspection target may be in an open state.

In an embodiment, in the first inspection method, a first terminal of the built-in switch may be connected to a node between the current driving unit and the PWM switch, and a second terminal of the built-in switch may be connected to a corresponding test line. Referring to FIG. 3A, it is shown that a first terminal of the built-in switch 361 of the driving circuit 311 is connected to a node between the current driving unit and the PWM switch of the driving circuit 311, a first terminal of the built-in switch 362 of the driving circuit 312 is connected to a node between the current driving unit and the PWM switch of the driving circuit 312, and second terminals of the built-in switch 361 and the built-in switch 362 are each connected to the test line.

Meanwhile, in an embodiment, a built-in switch included in driving circuits according to the first inspection method may be a digital element. In an example shown in FIG. 3A, the built-in switch 361 and the built-in switch 362 may be digital elements.

The first inspection method according to the embodiment shown in FIG. 3A may be mainly intended to inspect an operation for the PWM signal in an open state of the light-emitting element connection portion.

Based on the first inspection method according to the embodiment shown in FIG. 3A, due to a restriction, etc., such as sizes of elements, application to a display driving device for driving a display device having a small pixel size may be possible. FIG. 3B schematically shows a connection state of circuits in an inspection mode according to the second inspection method.

In FIG. 3B, a driving circuit 321 may be a driving circuit selected as an inspection target, and a driving circuit 322 may be a driving circuit not selected as an inspection target. In an embodiment, the driving circuit 321 and the driving circuit 322 may be driving circuits included in one column.

As described above, the second inspection method may be a method of inspecting the driving circuit both in a state in which the display driving device and the light-emitting element array are coupled and in a state in which the display driving device and the light-emitting element array are not coupled, and FIG. 3B regards an embodiment in the state where the display driving device and the light-emitting element array are coupled. Thus, unlike FIG. 3A, light-emitting elements may be connected to the light-emitting element connection portion of the driving circuits shown in FIG. 3B.

Referring to FIG. 3B, the driving circuit 321 may be electrically connected to the inspection circuit, but the driving circuit 322 may not be electrically connected to the driving circuit 321 and the inspection circuit. Specifically, the driving circuit 321 may be electrically connected to the test line such that an inspection signal for inspecting the operation of the driving circuit 321 may be extracted, and the test line may be electrically connected to the inspection circuit. The inspection circuit will be described in detail later.

In the present disclosure, the driving circuits (e.g., the driving circuit 321 and the driving circuit 322) that may be selected as inspection targets may include built-in switches having adjustable electrical connections to the corresponding test line (or the inspection circuit). When selected as an inspection target, a built-in switch included in the driving circuit is closed, thereby forming an electrical connection between the driving circuit and the test line (or inspection circuit). Referring to FIG. 3B, a built-in switch 371 of the driving circuit 321 selected as an inspection target may be in a closed state, but a built-in switch 372 of the driving circuit 322 not selected as an inspection target may be in an open state.

In an embodiment, in the second inspection method, a first terminal of the built-in switch may be connected to a node between the light-emitting element connection portion and the current driving unit, and a second terminal of the built-in switch may be connected to a corresponding test line. Referring to FIG. 3B, it is shown that a first terminal of the built-in switch 371 of the driving circuit 321 is connected to a node between the light-emitting element connection portion and the current driving portion of the driving circuit 321, a first terminal of the built-in switch 372 of the driving circuit 322 is connected to a node between the light-emitting element connection portion and the current driving unit of the driving circuit 322, and second terminals of the built-in switch 371 and the built-in switch 372 are respectively connected to the test line.

In summary, in the first inspection method schematically described with reference to FIG. 3A, as the light-emitting element connection portion is open, an inspection function may be implemented by forming an electrical connection between a driving circuit included in an active area and a test line by using a driving circuit included in an inactive area,. In the second inspection method schematically described with reference to FIG. 3B, switches are placed on the driving circuits, and, as will be described later, a switch may be arranged in driving circuits, and a switch may be arranged in an inspection circuit as described below, thereby selectively forming an electrical connection between the driving circuit and the inspection circuit and thus implementing an inspection function.

Meanwhile, in an embodiment, a built-in switch included in driving circuits according to the second inspection method may be an analog element. In the example of FIG. 3B, the built-in switch 371 and the built-in switch 372 may be analog elements.

Meanwhile, although not shown in FIG. 3B, as described above, the second inspection method may also be applied to a display driving device to which the light-emitting element array is not coupled. In the display driving device before being coupled to the light-emitting element array, the light-emitting element connection portion of the driving circuit is in an open state, such that also in this state, through control of the built-in switch included in the driving circuit, only the driving circuit selected as an inspection target may be connected to the inspection circuit. In this way, the operation of the driving current and the PWM signal of the driving circuit selected as the inspection target may be inspected.

The second inspection method according to the embodiment shown in FIG. 3B may aim to inspect the operation of the driving current and the PWM signal in the open state of the light-emitting element connection portion, or inspect the characteristic signal, etc., of the light-emitting element, in a state where the light-emitting element is connected to the light-emitting element connection portion. That is, when the light-emitting element connection portion is open, the inspection signal may include the operation of the driving current and the PWM signal, and when the light-emitting element is connected to the light-emitting element connection portion, the inspection signal may include a feature signal of the light-emitting element. One of the main characteristics for implementing the second inspection method may be the placement of the built-in switch of the driving circuit.

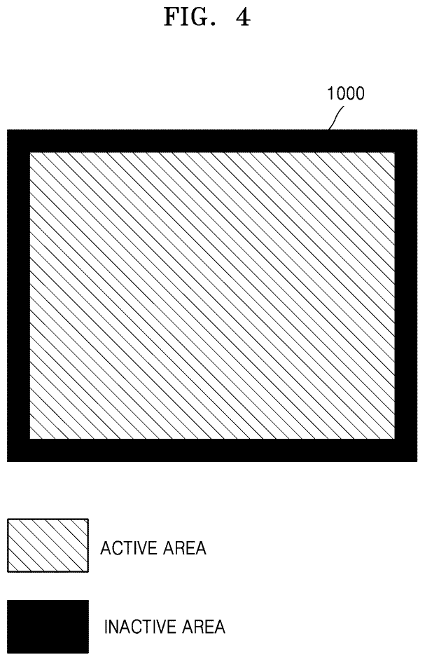

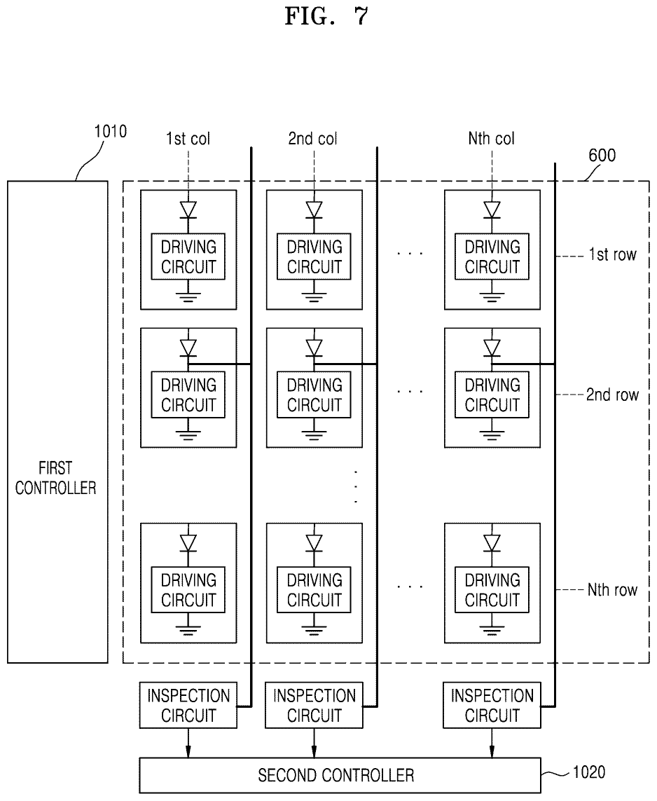

Hereinafter, the first inspection method schematically described through FIG. 3A will be described in detail with reference to FIGS. 4 to 6, and the second inspection method schematically described with reference to FIG. 3B will be described with reference to FIGS. 7 to 10.

FIG. 4 is a schematic diagram for describing an active area and an inactive area of a driving circuit unit, according to an embodiment of the present disclosure.

As shown in FIG. 4, a driving circuit unit 1000 according to an embodiment of the present disclosure may include an active area and an inactive area.

In the present disclosure, an active area may refer to an area associated with light emission and non-light emission of a light-emitting device in a driving mode. The driving mode may refer to a state in which a light-emitting element is driven by a driving circuit in order for the display device to display input image data. In an embodiment, the active area may include one or more driving circuits.

In the present disclosure, an inactive area or a dummy area may refer to an area that is not associated with light emission or non-light emission of a light-emitting device in a driving mode. The inactive area may be an area for protecting the active area directly related to light emission and non-light emission of the light-emitting element, and may be an area that may occur during the production of a display driving device or a display device. For the purpose of protecting the active area, the inactive area may be formed to surround the active area. Accordingly, as shown in FIG. 4, the inactive area may be formed at each corner of the driving circuit unit 1000.

Thus, the inactive area may include one or more driving circuits, but the driving circuit included in the inactive area may not operate normally in the driving mode. That is, the driving circuit included in the inactive area may not be associated with light emission or non-light emission based on image data. In an embodiment, the driving circuit included in the inactive area of the display device may not be connected to the light-emitting element. For example, the driving circuit included in the inactive area may have an open point corresponding to a portion connected to the light-emitting device.

Meanwhile, referring to FIG. 4, it is shown that an inactive area is formed at each corner of the rectangular driving circuit unit 1000, but an inactive area may be located arbitrarily within the driving circuit unit 1000. However, when the driving circuit unit 1000 includes a rectangular array of driving circuits, the inactive area may be preferably located at the edge of the driving circuit unit 1000.

In addition, the inactive area may include driving circuit units in a row direction (i.e., at least one column) or driving circuit units in a column direction (i.e., at least one row), in the driving circuit unit 1000. The position of the inactive area does not limit the present disclosure.

Accordingly, hereinafter, the display driving device and the display device according to the present disclosure will be described on an assumption that the inactive area includes the last rows among one or more rows including one or more driving circuits.

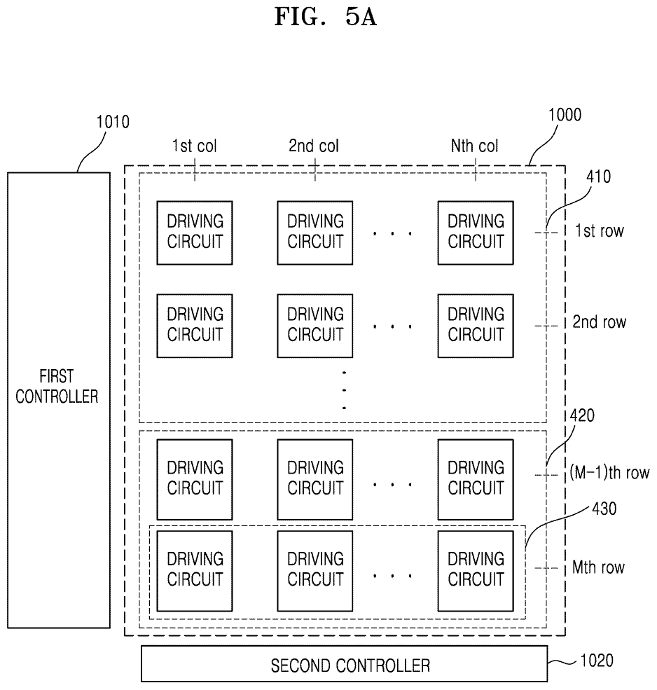

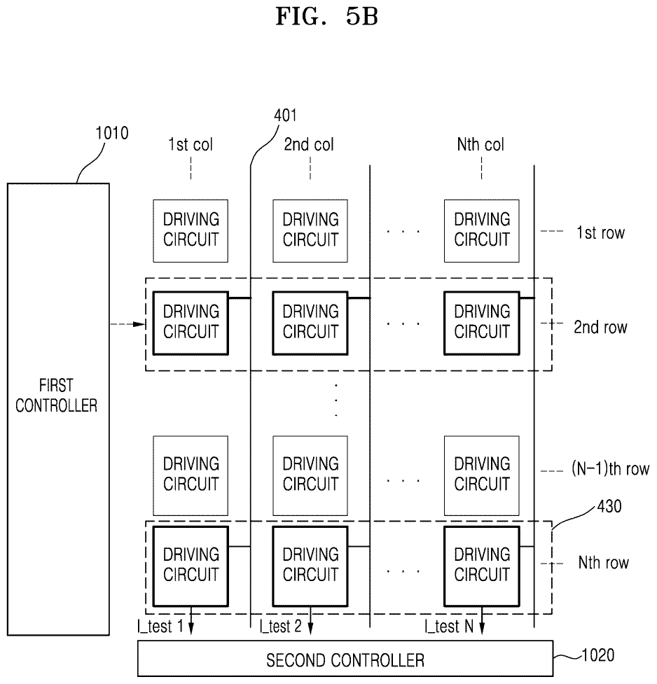

Hereinafter, an inspection method according to an embodiment of the present disclosure will be described with reference to FIGS. 5A and 5B. The inspection method described below may correspond to a method for inspecting driving circuits included in the display driving device before the light-emitting element array is coupled thereto, that is, the first inspection method. Accordingly, the light-emitting element connection portion of the driving circuit included in the display driving device described with reference to FIGS. 5A and 5B may be open.

The display driving device according to the present disclosure may implement an inspection function by using the inactive area included in the driving circuit unit 1000. In the present disclosure, a region of the inactive area, used to implement the inspection function, may be referred to as an inspection function implementation area.

FIGS. 5A and 5B are diagrams schematically showing a display driving device according to an embodiment related to the first inspection method of the present disclosure.

The display driving device of FIGS. 5A and 5B may correspond to the display driving device 20 described above with reference to FIG. 1.

Referring to FIG. 5A, the display driving device may include the driving circuit unit 1000.

The driving circuit unit 1000 may include an array of a plurality of driving circuits arranged in various patterns such as a predetermined pattern, for example, a matrix pattern, a zigzag pattern, etc. FIGS. 5A and 5B show an array of a plurality of driving circuits arranged in a matrix pattern.

In an embodiment, the driving circuit array may include a plurality of driving circuits and may include columns and rows including the driving circuits. Specifically, the driving circuit array may form one or more rows including one or more driving circuits and one or more columns including one or more driving circuits. In an example shown in FIG. 5A, the driving circuit unit 1000 may include a driving circuit array including M rows and N columns.

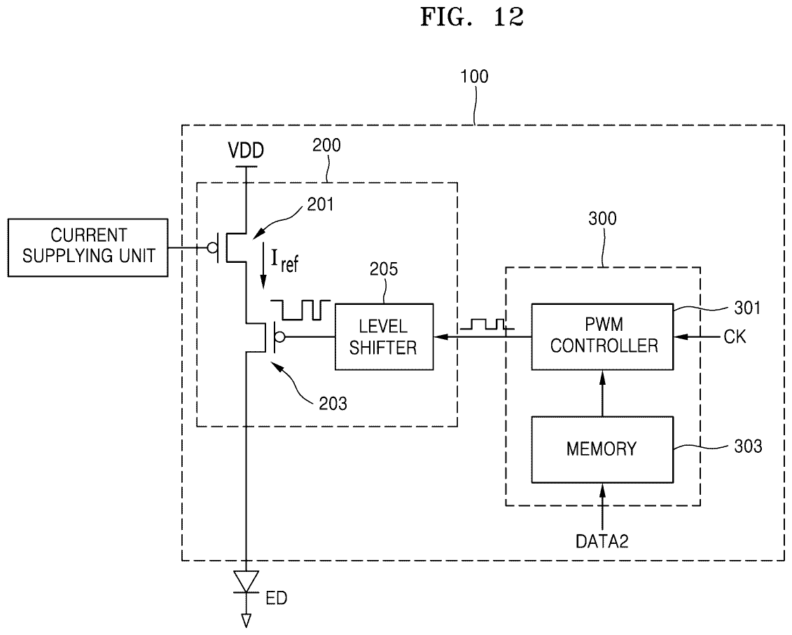

For convenience of a description, a specific configuration of the driving circuit is not shown in FIGS. 5A and 5B, but will be described in detail with reference to FIG. 12.

In an embodiment, the driving circuit may include a component that controls light emission and non-light emission of the light-emitting element in response to a control signal (hereinafter, referred to as a control signal switch for convenience of description) after the driving circuit unit and the light-emitting element array are coupled to each other, and a component that transfers driving current to the light-emitting element.

Meanwhile, the driving circuit according to an embodiment of the present disclosure may be characterized by being able to implement inspection of the driving circuits before the driving circuit unit and the light-emitting element array are coupled, such that the driving circuit unit 1000 shown in FIGS. 5A and 5B may be considered as not being coupled to the light-emitting element array. In other words, the driving circuits shown in FIGS. 5A and 5B may be considered as not being coupled to the light-emitting element.

Thus, in an embodiment, the driving circuit included in the active area 410 is not electrically connected to the light-emitting device, and thus a configuration through which the driving current is transmitted may be incomplete. For example, in the driving circuit included in the active area 410, a conductive wire of a portion through which the driving current flows may be open.

However, a control signal switch of the driving circuit included in the active area 410 may operate normally. That is, the driving circuit according to an embodiment of the present disclosure may be inspected to determine whether light emission and non-light emission of the light-emitting element are normally adjustable in response to a control signal, and the control signal switch may normally operate independently of coupling to the light-emitting element. Whether light emission and non-light emission of the light-emitting device may be normally controlled in response to the control signal may be inspected by measuring current through an electrical connection between the driving circuit included in the active area 410 and a driving circuit included in an inspection function implementation area 430, as will be described below. Meanwhile, in an embodiment, a control signal switch of a specific driving circuit may be implemented to operate independently of whether the driving circuit is subject to an inspection function. In another embodiment, the control signal switch of the specific driving circuit may be implemented to be “ON” when that driving circuit is subject to the inspection function. On the other hand, as the driving circuit included in the inactive area 420 may not operate normally in the driving mode, the control signal switch of the driving circuit included in the inactive area 420 may not operate normally. For example, the control signal switch of the driving circuit included in the inactive area 420 may be open.

As will be described later, the display driving device according to the present disclosure may implement the inspection function by forming an electrical connection between a driving circuit to be inspected and the driving circuit included in the inspection function implementation area 430. Accordingly, unlike the driving circuit included in the active area 410, the driving circuit included in the inspection function implementation area 430 may be configured to allow current to flow through the electrical connection formed between the driving circuit to be inspected and the driving circuit included in the inspection function implementation area 430.

Implementation of the inspection function will be described below, assuming the characteristics of the driving circuit in each area described above.

In an embodiment, the display driving device may include a first controller 1010 and a second controller 1020.

In an embodiment, the first controller 1010 and the second controller 1020 may be connected to driving circuits of a driving circuit unit in which a plurality of pixel driving circuits included in the display driving device are arranged in rows and columns. In an embodiment, the first controller 1010 may be connected to the pixel driving circuits of the driving circuit unit on a row-by-row basis, and the second controller 1020 may be connected to the pixel driving circuits of the driving circuit unit on a column-by-column basis.

Specifically, the first controller 1010 may be connected to each of one or more rows, and in an embodiment, one or more rows connected to the first controller 1010 may be included in the active area 410. The second controller 1020 may be connected to each of one or more columns, and in an embodiment, one or more columns connected to the second controller 1020 may be included in the active area 410. In other words, the first controller 1010 and the second controller 1020 may be connected to each row and column included in the active area 410. In FIGS. 5A and 5B, for convenience of a description, the connection between the first controller or the second controller and the driving circuits is omitted.

In the present disclosure, the first controller 1010 and the second controller 1020 may set a driving circuit to be inspected in an inspection mode. In the inspection mode, the first controller 1010 and the second controller 1020 may generate and supply a signal according to a control signal (e.g., generated by the controller 121, which will be described later), and by the supplied signal, In the inspection mode according to the present disclosure, the operation of the driving circuits can be controlled. The inspection mode may refer to a state for inspecting whether a manufactured display driving device has been manufactured normally.

Meanwhile, each of the first controller 1010 and the second controller 1020 may be included in a clock generating unit (described later) or a data driving unit (described later), or may be configured separately from the clock generating unit or the data driving unit. In an embodiment, the first controller 1010 and the second controller 1020 may be controlled by a component capable of controlling the operation of the display driving device, for example, a controller 121 described below, specifically, a processor configured to control the operation of the display driving device.

Referring to FIG. 5A, the driving circuit unit 1000 may include a plurality of driving circuits, which may form M rows and N columns.

Referring to FIG. 5A, the driving circuit unit 1000 may include the active area 410 and the inactive area 420, and the inactive area 420 may include the inspection function implementation area 430.

Specifically, the last two rows of the driving circuit unit 1000, an (M-1)^{th} row and an M^{th} row, may form the inactive area 420. As shown in FIG. 5A, each of the (M-1)^{th} row and the M^{th} row may include N driving circuits.

As described above, the inactive area according to the present disclosure may include the inspection function implementation area 430. In an embodiment, any one of the rows included in the inactive area 420 may be the inspection function implementation area 430. In the example shown in FIG. 5A, the M^{th} row of the inactive area 420 may correspond to the inspection function implementation area 430. That is, in the example shown in FIG. 5A, the inspection function implementation area 430 may be utilized to implement the inspection function, and the driving circuit included in the inspection function implementation area 430 may not operate in the driving mode, but may operate in the inspection mode.

FIG. 5B is a diagram for describing the implementation of the inspection function in the inspection mode.

As described above, the driving circuit included in the inspection function implementation area 430 may not operate in the driving mode, but may operate in the inspection mode. When the driving circuit included in the inspection function implementation area 430 operates in the inspection mode, it may mean that a current flow may be formed through an electrical connection to the driving circuit to be inspected.

The display driving device according to the present disclosure may implement the inspection function by forming an electrical connection between a driving circuit to be inspected and the driving circuit included in the inspection function implementation area 430. As described above, an inspection target may be set by the first controller 1010 and the second controller 1020.

In an embodiment, the first controller 1010 may select at least one of one or more rows as a row to be inspected. In an embodiment, the second controller 1020 may select at least some of the driving circuits included in the row to be inspected as an inspection target.

In the example shown in FIG. 5B, the second row may be selected as the row to be inspected, by the first controller.

Specifically, the first controller 1010 may generate and supply a signal for selecting the second row, and an electrical connection between the driving circuits included in the second row and a corresponding test line may be formed by the supplied signal. In an embodiment, the driving circuit included in the active area 410 may include a switch whose electrical connection to the corresponding test line is controllable, and the switch may be controlled by the first controller 1010.

Each test line may also be connected to the driving circuit included in the inspection function implementation area 430. Accordingly, each of the driving circuits included in the row to be inspected, selected by the first controller 1010, may form an electrical connection to the driving circuit of the corresponding inspection function implementation area 430.

Referring to the first column of FIG. 5B, it is shown that an electrical connection is generated between the driving circuit included in the second row and the driving circuit included in the inspection function implementation area 430 through a test line 401.

In the present disclosure, as the electrical connection is generated between the driving circuit included in the active area 410 and the driving circuit included in the inspection function implementation area 430, test current may be generated, and by measuring the test current, whether or not the driving circuit included in the active area 410 operates normally, electrical characteristics of the driving circuit, etc., may be detected.

Specifically, as described above, the control signal switch of the driving circuit to be inspected may operate normally, and the electrical characteristics of the driving circuit to be inspected according to the operation of the control signal switch may be transmitted through the test line 401, and such electrical characteristics may be transmitted to the driving circuit included in the inspection function implementation area 430 and expressed as test current. As a result, the test current may feature an operation based on the control signal of the driving circuit to be inspected.

Meanwhile, in an embodiment, the second controller 1020 may selectively receive the test current. That is, the second controller 1020 may control to inspect whether some of the driving circuits included in the row to be inspected operate, which may be realized by receiving test current for some of one or more columns. For example, the second controller 1020 may control an electrical connection between the driving circuit included in the inspection function implementation area 430 and the test line. Specifically, the driving circuit included in the inspection function implementation area 430 may include a switch whose electrical connection to the corresponding test line is controllable, and the switch may be controlled by the second controller 1020.

For example, if the purpose is only to measure “I_test 1”, which is the test current for the first column, the second controller 1020 can generate and supply a signal to select the first column, and add a signal to the supplied signal. As a result, an electrical connection with the test line can be created only for the driving circuit of the inspection function implementation area 430 included in the first column.

Accordingly, in an embodiment, the driving circuit unit 1000 may include one or more test lines, and the number of one or more test lines may equal the number of columns included in the driving circuit unit 1000.

The example described above with reference to FIG. 5B relates to the inspection of a driving circuit included in one row selected by the first controller, that is, one of the driving circuits included in one column, but in an embodiment, a plurality of rows may be selected, such that operations of the plurality of driving circuits included in one column may be verified and current characteristics of the plurality of driving circuits may be identified.

Moreover, in the example described above with reference to FIG. 5B, the inspection function implementation area includes one row, but the inspection function implementation area may include one or more rows.

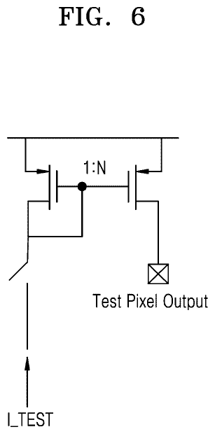

FIG. 6 shows a current amplifying circuit for amplifying test current according to an embodiment of the present disclosure.

Micro LEDs are quite small in size and generally operate with small current, such that when a small number (e.g., one) of driving circuits are inspected, a corresponding test current may have a very small value. That is, in the example shown in FIG. 5B, test currents I_test 1, I_test 2, . . . I_test N may be very small in magnitude. To compensate for this, in an embodiment, the display driving device may further include a current amplifying circuit.

Referring to FIG. 6, the current amplifying circuit may amplify input test current I_test and output the same to an output terminal Test Pixel Output.

In an embodiment, the current amplifying circuit may be disposed on the display driving device. Specifically, the current amplifying circuit may be electrically connected to a driving circuit included in the inspection function implementation area. For example, the current amplifying circuit may be arranged to be included in the driving circuit included in the inspection function implementation area. For example, the current amplification circuit may be arranged to be included in the first controller or the second controller (in the example shown in FIG. 4B, the second controller) depending on the arrangement of the inspection function implementation area.

Hereinafter, an inspection method according to another embodiment of the present disclosure will be described with reference to FIGS. 7 to 10. The inspection method described below may correspond to a method for inspecting elements in a state where a display driving device and a light-emitting element array are coupled to each other, i.e., the second inspection method. Accordingly, the light-emitting element may be connected to each driving circuit included in the display driving device described with reference to FIGS. 7 to 10.

FIG. 7 is a diagram schematically showing a display driving device coupled to a light-emitting element array according to an embodiment related to the second inspection method of the present disclosure.

FIG. 7 relates to an example of inspecting the driving circuits of the display driving device after the light-emitting element array is coupled thereto, but the following description may be analogically applied to the display driving device before the light-emitting element array is coupled thereto.

FIG. 7 is a diagram for describing the implementation of an inspection method according to another embodiment of the present disclosure.

As shown in FIG. 7, unlike FIGS. 5A and 5B, FIG. 7 is a diagram of a display driving device to which a light-emitting element array is coupled.

As described above with reference to FIG. 1, the display device 30 may include the light-emitting element array 10 and the display driving device 20, and the light-emitting element array 10 may be coupled to the display driving device 20. The light-emitting element array 10 may include a plurality of light-emitting elements, and the light-emitting element array 10 may be coupled to the display driving device 20 without a need to individually transfer the light-emitting elements to the display driving device 20, such that the display device 30 may be manufactured.

Referring to FIG. 7, unlike FIG. 5A, it is shown that a light-emitting element is connected to each of the driving circuits, and in this way, it would be understood that the light-emitting element array is coupled to the display driving device.

In an embodiment, a light-emitting device coupled to a driving circuit may be referred to as a pixel PX. That is, the light-emitting element array may be coupled to the driving circuit unit (e.g., the driving circuit unit 1000) to form a pixel array 600. FIG. 7 shows the pixel array 600 arranged in a predetermined pattern, for example, a matrix pattern.

In an embodiment, the pixel array 600 may include the plurality of pixels PX and may include columns and rows composed of the pixels PX.

In the current embodiment, the display driving device may include an inspection circuit. In an embodiment, the inspection circuit may be provided corresponding to each column. The inspection function may be implemented by forming an electrical connection between the pixel PX to be inspected and the inspection circuit.

Referring to FIG. 7, the display driving device may include the first controller 1010 and the second controller 1020.

In one embodiment, the first controller 1010 and the second controller 1020 may be connected to driving circuits of a driving circuit unit in which a plurality of pixel driving circuits included in the display driving device are arranged in rows and columns. In one embodiment, the first controller 1010 may be connected to the pixel driving circuits of the driving circuit unit on a row-by-row basis, and the second controller 1020 may be connected to the pixel driving circuits of the driving circuit unit on a column-by-column basis. In FIG. 7, each of the plurality of pixel driving circuits is connected to a light-emitting element of the light-emitting element array, and as a result, in the example of FIG. 7, the first controller 1010 and the second controller 1020 may be connected to each of a plurality of devices arranged in rows and columns.

In one embodiment, the first controller 1010 and the second controller 1020 may be connected to a plurality of pixels (PX) included in the pixel array 600. Specifically, the first controller 1010 may be connected to each of one or more rows, and the second controller 1020 may be connected to each of one or more columns.

In one embodiment, the first controller 1010 and the second controller 1020 may set a pixel (PX) to be inspected in an inspection mode.

Specifically, the first controller 1010 may select at least one of one or more rows, and the second controller 1020 may select, as the inspection target, at least some of the pixels (PX) included in the row to be inspected selected by the first controller 1010. The row subject to inspection by the first controller 1010 may be electrically connected to the inspection circuit through a test line.

Referring to FIG. 7, the second row is set as the target of inspection by the first controller 1010, and an electrical connection is formed between the pixel PX included in the second row and the inspection circuit.

Meanwhile, the second controller 1020 may selectively receive electrical signals (e.g., current or voltage) from one or more inspection circuits. For example, in the example shown in FIG. 7, the second controller 1020 may receive an electrical signal from the inspection circuit corresponding to the second column. In this case, as a result, an inspection can be performed on the pixel (PX) located in the second column of the second row.

Meanwhile, in order to enable the first controller 1010 to select at least one of one or more rows, a switch may be included in the display driving device. For example, the pixel PX (or driving circuit) may include a switch, and the switch may be controlled by the first controller 1010. When the pixel PX (or row) is selected by the first controller 1010, the switch of the selected pixel PX (or the pixel PX included in the row) is closed, and the pixel PX (or the pixel PX included in the row) may be electrically connected to a test line or inspection circuit.

Additionally, a switch for enabling the second controller 1020 to selectively receive an electrical signal from one or more inspection circuits may be included in the display driving device. For example, the inspection circuit may include a switch, and the switch may be controlled by the second controller 1020. When a column is selected by the second controller 1020, a switch included in the inspection circuit corresponding to the selected column is closed, and the pixel PX to be inspected may be electrically connected to the inspection circuit. For example, the switch included in the inspection circuit may adjust the electrical connection to the test line.

In an embodiment, the first controller 1010 and the second controller 1020 may be respectively included in a clock generating unit (described later) or a data driving unit (described later), or may be configured separately from the clock generating unit or data driving unit.

Meanwhile, in FIG. 7, the inspection circuit is shown as being provided outside the second controller 1020, but the inspection circuit may be implemented in any manner within the display driving device. For example, the second controller 1020 may include an inspection circuit.

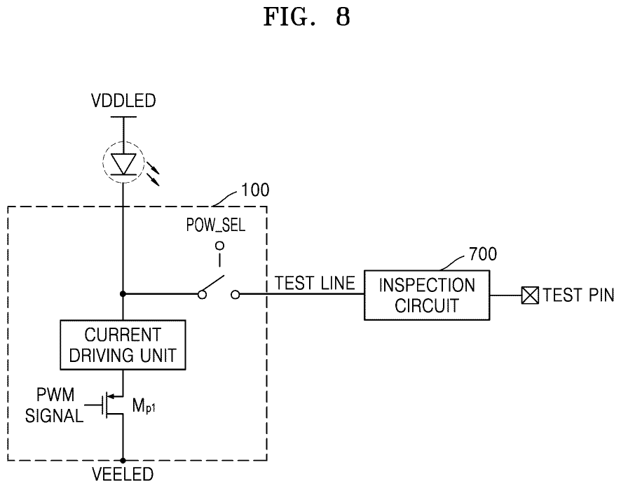

FIG. 8 is a diagram for specifically describing an inspection method according to an embodiment related to the second inspection method of the present disclosure.

FIG. 8 may be related to the embodiment described with reference to FIG. 7, and specifically shows a pixel PX and an inspection circuit set as an inspection target in FIG. 7.

Referring to FIG. 8, a pixel PX set as an inspection target may include a light-emitting element and a driving circuit 100.

In an embodiment, the driving circuit 100 may include a current driving unit and a PWM switch M_{P1}.

In an embodiment, the current driving unit may drive the current required for the pixel PX, that is, supply the current required for driving the light-emitting element, and the current driving unit, like the first transistor 201 described below, may be provided outside the pixel PX and may be configured to receive and output current from a current supplying unit that supplies current to one or more pixels PX, and may include a bias circuit provided in each pixel PX.

In an embodiment, the PWM switch M_{P1} may transfer or block driving the current to the light-emitting element according to the PWM signal. In an embodiment, the PWM switch M_{P1} may correspond to the second transistor 203, which will be described later.

For convenience of description of the inspection method according to the current embodiment, specific components are omitted, but the driving circuit 100 of FIG. 8 may correspond to the driving circuit 100 of FIG. 12, and may include all or some of the components included in the driving circuit 100 of FIG. 12.

The inspection method according to the current embodiment may inspect the performance of the pixel PX or display device by measuring a voltage V_{A} of Node A. Node A may be a node where the driving circuit 100 and the light-emitting element are connected. Information that may be obtained by measuring V_{A} will be described later.

As described above, when a row is selected by the first controller 1010, the switch of the pixel PX included in the selected row is closed, and the pixel PX may be electrically connected to a test line or inspection circuit. Accordingly, an inspection signal may be extracted from the pixel PX.

Referring to FIG. 8, in an embodiment, the driving circuit 100 may include a built-in switch, and the built-in switch may be configured to control the electrical connection between the driving circuit 100 and the test line. As described above, the first terminal of the built-in switch may be connected to the node between the light-emitting element connection portion and the current driving unit, and the second terminal of the built-in switch may be connected to a test line. In an embodiment, this switch may be controlled by a signal ROW_SEL. The signal ROW_SEL may be a signal for selecting a row. In an embodiment, the signal ROW_SEL may be generated by the first controller 1010.

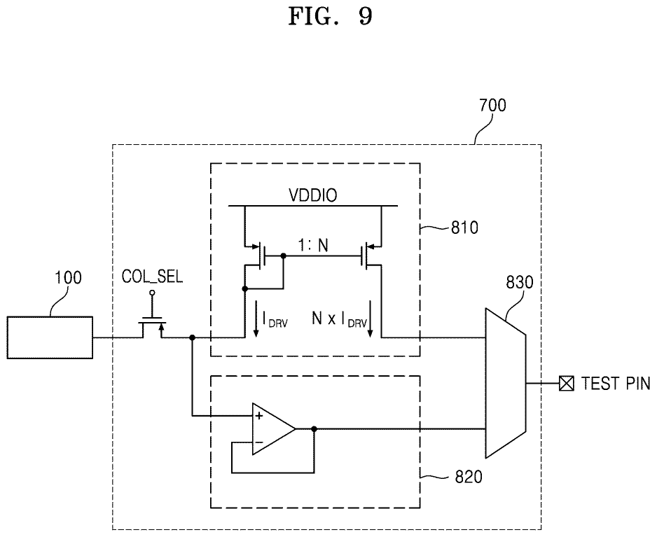

Referring to FIG. 8, in an embodiment, when the switch is closed by the signal ROW_SEL, the driving circuit 100 may be electrically connected to the inspection circuit 700, and a test signal can be input to an inspection circuit 700. In an embodiment, the inspection circuit 700 may be connected to a TEST PIN included in the display driving device. Through the TEST PIN, a value indicating the performance of the pixel PX may be measured. The inspection circuit 700 according to the present disclosure will be described in detail later with reference to FIG. 9.

FIG. 9 is a circuit diagram for describing an inspection circuit according to an embodiment related to the second inspection method of the present disclosure.

In an embodiment, the inspection circuit 700 may include a current detecting circuit 810 and a voltage detecting circuit 820.

The current detecting circuit 810 may be a circuit capable of detecting current (i.e., driving current) flowing in the driving circuit 100 (the driving circuit 100 coupled to a light-emitting element). The current detecting circuit 810 may output current based on the inspection signal. Meanwhile, the current flowing in the driving circuit 100 may be small in magnitude. Accordingly, in an embodiment, the current detecting circuit 810 may include a current amplifying circuit.

The voltage detecting circuit 820 may be a circuit capable of detecting voltage of a node of the driving circuit 100 connected to the light-emitting element. The voltage detecting circuit 820 may output voltage based on the inspection signal. That is, in the examples of FIGS. 8 and 9, the voltage detecting circuit 820 may detect the voltage V_{A} of Node A. In an embodiment, the voltage detecting circuit 820 may include a buffer.

In an embodiment, the inspection circuit 700 may include a selector 830.

In an embodiment, the selector 830 may be connected to a TEST PIN, and whether to measure current or voltage through the TEST PIN may be determined by the selector 830. In an embodiment, the selector 830 may receive an input for selecting a measurement target, and output any one of a value output from the current detecting circuit 810 and a value output from the voltage detecting circuit 820, to the TEST PIN based on the input for selecting the measurement target. In an embodiment, the selector 830 may include a multiplexer mux. The input for selecting a measurement target may be input by a controller (e.g., the controller 121, which will be described later).

In an embodiment, the inspection circuit 700 may include a switch. This switch may be configured to control the electrical connection between the inspection circuit 700 and the driving circuit 100. That is, the inspection circuit 700 may include a switch in a portion connected to the driving circuit 100. In an embodiment, this switch may include a transistor. In an embodiment, this switch may be controlled by a signal COL_SEL. The signal COL_SEL may be a signal for selecting a column. In an embodiment, the signal COL_SEL may be generated by the second controller 1020. Referring to FIG. 9, when the switch is closed by the signal COL_SEL, the inspection circuit 700 may be electrically connected to the driving circuit 100 and receive an inspection signal from the driving circuit 100.

In an embodiment, the current or voltage detected through the TEST PIN may be measured. For example, a user may connect any suitable measuring device to the TEST PIN to measure detected current or voltage.

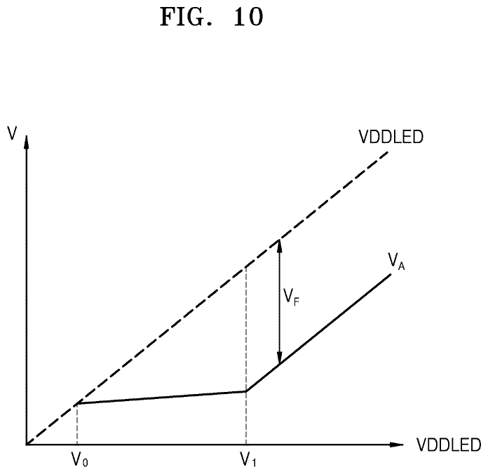

FIG. 10 is a graph for describing voltage characteristics analyzed using an inspection method according to an embodiment related to the second inspection method of the present disclosure.

FIG. 10 shows changes in the voltage V_{A} of Node A according to changes in a value VDDLED in the circuit of FIG. 8. The value VDDLED is a voltage supplied to the pixel PX and may actively change, and the value V_{A} may be changed passively as the value VDDLED changes. V_{A} may reflect the characteristics of manufactured elements, driving circuits, display devices, etc.

Referring to FIG. 10, when the value VDDLED gradually increases from 0 to V ₀, current may flow in the driving circuit 100, and V_{A} has a value that may equal V₀ equaling the value VDDLED. In other words, the light-emitting element may be in an OFF state in a section where the value VDDLED is less than V₀. This may be because in the range from 0 to V₀, the light-emitting element is in an off state and no current flows in the driving circuit, such that V_{A} may have the same value as VDDLED.

Referring to FIG. 10, in a section where the value VDDLED is less than V1, sufficient voltage may not be applied to the light-emitting element. That is, V₁ may mean the value VDDLED for applying sufficient voltage to the light-emitting element.

Referring to FIG. 10, the value VDDLED gradually increases from V₀ to V₁, such that when sufficient voltage is applied to the light-emitting element, the difference between the value VDDLED and the value V_{A} may become constant. That is, even when the value VDDLED increases, the voltage difference across opposite ends of the light-emitting element of FIG. 8 may remain constant. When the constant difference between the value VDDLED and the value V_{A} is referred to as V_{F}, V_{F} may represent characteristics of light-emitting elements, driving circuits, display devices, etc. That is, due to errors occurring during a manufacturing process and processing, V_{F} may be different even if the same type of element is used, such that the performance of the light-emitting element, the driving circuit, the display device, etc., may be evaluated through V_{F}.

V_{F} may be compared to a reference voltage. Here, the reference voltage may refer to the voltage applied to the light-emitting element when the light-emitting element operates normally. In other words, the reference voltage may mean a desirable operating voltage aimed in manufacturing of a light-emitting element.

In an embodiment, the driving current may be adjusted based on V_{F} and the reference voltage. In an embodiment, the controller (e.g., the controller 121 described below) may adjust the driving current based on V_{F} and the reference voltage.

For example, the controller may increase the driving current when V_{F} is less than the reference voltage. For example, the controller may reduce the driving current when V_{F} is greater than the reference voltage. In the case of light-emitting elements, generally, the higher the driving current is, the higher the operating voltage is, such that a suitable driving environment may be provided using such characteristics. In an embodiment, the degree to which the driving current is increased or decreased may be calculated using the characteristic curve of the light-emitting element. That is, the controller may increase or decrease the driving current as much as a difference between a current value corresponding to a target driving voltage value and the current driving current value based on the characteristic curve of the light-emitting element.

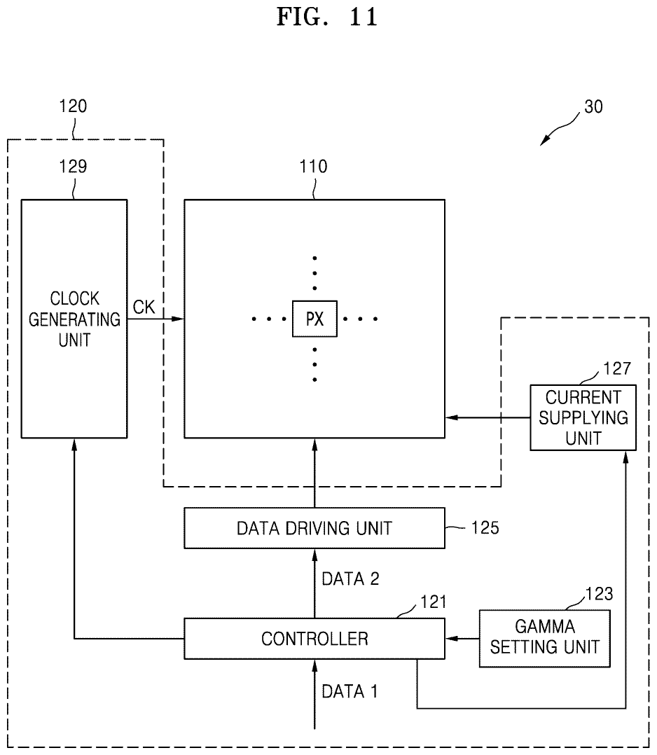

FIG. 11 is a diagram schematically showing a display device according to an embodiment of the present disclosure.

FIG. 11 may be a diagram illustrating the display device shown in FIG. 2 in more detail. Thus, the matters described in connection with FIG. 2 are omitted.

As described above, the display device 30 may be manufactured by coupling the light-emitting element array 10 to the display driving device 20.

Thus, the display device 30 may further include the above-described components according to various embodiments of the present disclosure, in addition to the components shown in FIG. 11. The components shown in FIG. 11 may be components that mainly operate in the driving mode.

In an embodiment, the driving unit 120 may include the controller 121, a gamma setting unit 123, the data driving unit 125, a current supplying unit 127, and the clock generating unit 129.

In an embodiment, the controller 121 may receive image data of one frame from an external source (e.g., a graphics controller), extract a grayscale for each pixel PX, and convert the extracted grayscale into digital data of a predetermined number of bits.

In an embodiment, the controller 121 may receive a correction value from the gamma setting unit 123 and perform gamma correction on input image data DATA1 using the correction value, thus generating corrected image data DATA2. The controller 121 may output the corrected image data DATA2 to the data driving unit 125. The controller 121 may output the MSB to the LSB of the corrected image data DATA2 to the data driving unit 125 in a predetermined order.

In an embodiment, the gamma setting unit 123 may set the gamma value using a gamma curve, set the correction value of the image data according to the set gamma value, and output the set correction value to the controller 121. The gamma setting unit 123 may be provided as a separate circuit from the controller 121 or may be included in the controller 121.

In an embodiment, the data driving unit 125 may transmit the corrected image data DATA2 from the controller 121 to each pixel PX of the pixel unit 110. The data driving unit 125 may provide a bit value included in the corrected image data DATA2 to each pixel PX for each frame. The bit value may have either a first logic level or a second logic level. The first logic level and the second logic level may be a high level and a low level, respectively. Alternatively, the first logic level and the second logic level may be a low level and a high level, respectively.

In an embodiment, one frame may include a plurality of sub-frames. The length of each subframe may be different. For example, the length of the subframe corresponding to the MSB of the corrected image data DATA2 may be set to be the longest, and the length of the subframe corresponding to the LSB may be set to be the shortest. The order of the MSB to the LSB of the corrected image data DATA2 may correspond to the order of the first subframe to the nth subframe, respectively. The order of expression of subframes may be set differently by a designer.

In an embodiment, the data driving unit 125 may include a line buffer and a shift register circuit. The line buffer may be a 1-line buffer or a 2-line buffer. The data driving unit 125 may provide image data of a specific bit to each pixel on a line-by-line (row-by-row) basis.

As described above, the second controller 1022 according to the present disclosure may correspond to the data driving unit 125. Therefore, depending on a design method, in an embodiment, the data driving unit 125 may further include a current amplifying circuit.

In an embodiment, the current supplying unit 127 may generate and supply driving current to each pixel PX.

In an embodiment, the clock generating unit 129 may generate a clock signal for each subframe during one frame and output the clock signal to the pixels PX. The length of the clock signal may be the same as the length of the corresponding subframe. The clock generating unit 129 may sequentially supply a clock signal to a clock line CL for each subframe. The clock generating unit 129 may generate a clock signal according to a predetermined sub-frame order. For example, when the order of expression of four subframes is 1-2-3-4, the clock generating unit 129 may sequentially output a first clock signal to a fourth clock signal in the order of the first subframe to the fourth subframe. When the output order of the four subframes is 1-3-2-4, the clock generating unit 129 generates the first clock signal in the order of the first subframe, the third subframe, the second subframe, and the fourth subframe. clock signals can be output in the following order: a third clock signal, a second clock signal, and a fourth clock signal. Meanwhile, the clock signal may include a control signal Sense, a control signal SPWM, and a control signal SPAM.

As described above, the first controller 1010 according to the present disclosure may correspond to the clock generating unit 129. Therefore, depending on a design method, in an embodiment, the clock generating unit 129 may further include a current amplifying circuit.

Each component of the driving unit 120 may be formed in the form of a separate integrated circuit chip or a single integrated circuit chip and may be mounted directly on a substrate on which the pixel unit 110 is formed, may be mounted on a flexible printed circuit film, may be attached to the substrate in the form of a tape carrier package (TCP), or may be directly on the substrate. In an embodiment, some of the controller 121, the gamma setting unit 123, the data driving unit 125, the current supplying unit 127, the clock generating unit 129, and the driving method selecting unit 130 may be connected to the pixel unit 110 in the form of an integrated circuit chip and some of them may be formed directly on the board.

FIG. 12 is a circuit diagram of a pixel PX according to embodiments of the present disclosure.

Referring to FIG. 12, the pixel PX may include a light-emitting element ED and a driving circuit 100 connected thereto. The driving circuit 100 of FIG. 12 may be a driving circuit included in the display driving device according to the various embodiments described above.

In an embodiment, the driving circuit 100 may include a first driving circuit 200 and a second driving circuit 300. The first driving circuit 200 may be a high-voltage driving circuit, and the second driving circuit 300 may be a low-voltage driving circuit. The second driving circuit 300 may be implemented with a plurality of logic circuits.

The light-emitting diode ED may selectively emit light for each subframe based on a bit value (logic level) of image data provided from the data driving unit (e.g., the data driving unit 125 in FIG. 11) during one frame, thereby adjust a light-emission time in one frame and displaying grayscales.

The first driving circuit 200 may adjust the emission or non-emission of the light-emitting element ED in response to a control signal applied to each of a plurality of subframes during one frame. The control signal may be a PWM signal. The first driving circuit 200 may include a first transistor 201, a second transistor 203, and a level shifter 205 that are electrically connected to a current supplying unit (e.g., the current supplying unit 127 in FIG. 11).

The first transistor 201 may output the driving current. The first transistor 201 may have a gate connected to a current supplying unit, a first terminal connected to a power voltage (VDD) source, and a second terminal connected to a first terminal of the second transistor 203.

The second transistor 203 may transmit or block the driving current to the light-emitting element ED according to the PWM signal. The second transistor 203 may have a gate connected to an output terminal of the level shifter 205, the first terminal connected to the second terminal of the first transistor 201, and a second terminal connected to the light-emitting element ED. Meanwhile, in an embodiment, the second transistor 203 may correspond to the control signal switch described above.

The second transistor 203 may be turned on or off depending on a voltage output from the level shifter 205. The light-emission time of the light-emitting element ED may be controlled according to the turn-on or turn-off time of the second transistor 203. The second transistor 203 may be turned on when a gate-on level signal is applied to the gate, thereby transmitting driving current output from the first transistor 201 to the light-emitting element ED to cause the light-emitting element ED to emit light. The second transistor 203 may be turned off when a gate-off level signal is applied to the gate, thereby blocking the driving current output by the first transistor 201 from being transmitted to the light-emitting element ED to cause the light-emitting element ED not to emit light. The light-emission time and non-light emission time of the light-emitting device ED are controlled by the turn-on time and turn-off time of the second transistor 203 during one frame, such that color depth may be expressed.

The level shifter 205 may be connected to an output terminal of a PWM controller 301 of the second driving circuit 300, and convert a voltage level of the first PWM signal output by the PWM controller 301 to generate a second PWM signal. The level shifter 205 may generate the second PWM signal for converting the first PWM signal into a gate-on voltage level signal capable of turning on the second transistor 203 and a gate-off level signal capable of turning off the second transistor 203.

The pulse voltage level of the second PWM signal output by the level shifter 205 may be higher than the pulse voltage level of the first PWM signal, and the level shifter 205 may include a boosting circuit that boosts the input voltage. The level shifter 205 may be implemented with a plurality of transistors.

The turn-on time and turn-off time of the second transistor 203 for one frame may be determined according to the pulse width of the first PWM signal.

The second driving circuit 300 may store the bit value of the image data applied from the data driving unit during a data write period for each frame and generate the first PWM signal based on the bit value and the clock signal during a light-emitting period. The second driving circuit 300 may include the PWM controller 301 and a memory 303.

The PWM controller 301 may generate the first PWM signal based on the clock signal CK input from the clock generating unit (e.g., the clock generating unit 129 of FIG. 11) and the bit value of the image data read from the memory 303. When the clock signal in subframe units is input from the clock generating unit, the PWM controller 301 may read the corresponding image data bit value from the memory 303 and generate the first PWM signal.

The PWM controller 301 may control the pulse width of the first PWM signal based on the bit value of the image data in subframe units and the signal width of the clock signal. For example, when the bit value of the image data is 1, the pulse output of the PWM signal may be turned on by the signal width of the clock signal, and when the bit value of the image data is 0, the pulse output of the PWM signal may be turned off by the signal width of the clock signal. That is, the on time and off time of the pulse output of the PWM signal may be determined by a signal width (signal length) of the clock signal. The PWM controller 301 may include one or more logic circuits (e.g., OR gate circuits, etc.) implemented with one or more transistors.

In synchronization with a frame start signal, the memory 303 may receive n-bit corrected image data DATA2 applied through a data line DL from the data driving unit during the data writing period and store the same in advance. For a still image, image data previously stored in the memory 303 may be continuously used to display an image for a plurality of frames until the image is updated or refreshed.

Bit values (logic levels) from the most significant bit (MSB) to the least significant bit (LSB) of the n-bit corrected image data DATA2 may be input to the memory 303 from the data driving unit in a predetermined order. The memory 303 may store data of at least 1 bit. In an embodiment, the memory 303 may be an n-bit memory. The bit values from the MSB to the LSB of the corrected image data DATA2 may be recorded in the memory 303 during the data writing period of the frame. In another embodiment, the memory 303 may be implemented as a memory of bits less than n, depending on the driving frequency. The memory 303 may be implemented with one or more transistors. The memory 303 may be implemented as random access memory (RAM), for example, SRAM or DRAM.

In the embodiment of FIG. 12, the current supplying unit may be connected to one pixel PX, but the current supplying unit may also be shared among a plurality of pixels PX.

In the above-described embodiment, an example in which the pixel includes P-type transistors is shown, but the embodiment of the present disclosure is not limited to thereto, and the pixel may include N-type transistors, and in this case, the pixel may be driven by a signal having an inverted level of a signal applied to P-type transistors.

At least some of the configurations according to the various embodiments described above may include processors, application-specific integrated circuits (ASICs), other chipsets, logic circuits, registers, communication modems, data processing devices, etc., known in the art to execute the various control logics described above. In addition, when the above-described control logic is implemented as software, it may be implemented as a set of program modules. In this case, the program module may be stored in a memory device and executed by a processor.

A program may include code coded in computer languages such as C/C++, C#, JAVA, python, or machine languages readable by a processor (CPU) of a computer through a device interface of the computer so as for the computer to read the program and execute methods implemented with the program. Such code may include functional code related to functions that define the necessary functions for executing the methods, and may include control code related to an execution procedure necessary for the computer's processor to execute the functions according to a predetermined procedure. In addition, such code may further include memory reference-related code regarding a position (address) in an internal or external memory of the computer at which additional information or media required for the computer's processor to execute the functions is to be referred to. Moreover, when communication with another computer, a server, etc., located remotely is required for execution of the functions by the computer's processor, the code may further include communication-related code regarding how to communicate with the other computer, the server, etc., located remotely using a communication module of the computer, which information or media is to be transmitted in communication, etc.

A storage medium in which a program is stored may not be a medium that stores data for a short period of time, such as a register or cache memory, but may be a medium that stores data semi-permanently and may be read by a device. Specifically, examples of the storage medium may include, but not limited to, read-only memory (ROM), RAM, compact disc (CD)-ROM, magnetic tape, floppy disk, optical data storage devices, etc. That is, the program may be stored in various recording media on various servers that the computer may access or in various recording media on the user's computer. Moreover, the storage medium may be distributed over computer systems connected through a network to store and execute a computer-readable code in a distributed manner.

It would be understood by those of ordinary skill in the art that the present disclosure may be implemented in a modified form within a scope without departing from the essential characteristics of the present disclosure. Thus, the spirit of the present disclosure should not be determined by being limited to the above-described embodiments, and not only the claims set forth below, but also any range equivalent to or equivalently changed from the claims falls within the scope of the spirit of the present disclosure.

1. A display driving device comprising:
a driving circuit unit in which a plurality of pixel driving circuits are arranged in rows and columns;
a first controller connected to the plurality of pixel driving circuits on a row-by-row basis;
a second controller connected to the plurality of pixel driving circuits on a column-by-column basis; and
one or more inspection circuits electrically connected to an inspection target pixel driving circuit selected by the first controller and the second controller to extract an inspection signal of the inspection target pixel driving circuit.

2. The display driving device of claim 1, wherein
each of the plurality of pixel driving circuits comprises:
a current driving unit configured to supply driving current required for driving a light-emitting element; and
a pulse width modulation (PWM) switch configured to transfer the driving current to the light-emitting element or block the same according to a PWM signal.

3. The display driving device of claim 2, wherein
the current driving unit is an analog element, and
the PWM switch is a digital element.

4. The display driving device of claim 2, wherein
each of the plurality of pixel driving circuits comprises a first switch having an adjustable electrical connection to a corresponding test line that transfers the inspection signal to the inspection circuit, and
the first switch is controlled by a signal generated by the first controller.

5. The display driving device of claim 4, wherein
a first terminal of the first switch is connected to a node between the current driving unit and a light-emitting element connection portion, and
a second terminal of the first switch is connected to the corresponding test line.

6. The display driving device of claim 4, wherein
the first switch is an analog element.

7. The display driving device of claim 1, wherein
each of the one or more inspection circuits comprises a second switch controlled by a signal generated by the second controller.

8. The display driving device of claim 1, wherein
each of the one or more inspection circuits comprises:
a current detecting circuit configured to output current based on the inspection signal;
a voltage detecting circuit configured to output voltage based on the inspection signal; and
a selector configured to select and output any one of a value output from the current detecting circuit and a value output from the voltage detecting circuit.

9. The display driving device of claim 1, further comprising
a plurality of light-emitting elements respectively connected to the plurality of pixel driving circuits,
wherein the inspection signal is a characteristic signal of the light-emitting element connected to the inspection target pixel driving circuit.
